(19) United States
(12) Patent Application Publication
(10) Pub. No.: US 2026/0051903 A1
(43) Pub. Date: Feb. 19, 2026

(54) WIRELESS COMMUNICATION TERMINAL, METHOD OF DECODING POLAR CODE, AND DECODING MODULE

(71) Applicant: ELECTRONICS AND TELECOMMUNICATIONS RESEARCH INSTITUTE, Daejeon (KR)

(72) Inventors: Jung-Im Kim, Daejeon (KR); Young Jo Ko, Daejeon (KR); Hee Sang Chung, Daejeon (KR); Yong Seouk Choi, Daejeon (KR)

(21) Appl. No.: 19/297,503

(22) Filed: Aug. 12, 2025

(30) Foreign Application Priority Data
Aug. 14, 2024 (KR) 10-2024-0108874
May 16, 2025 (KR) 10-2025-0064059

(51) Int. Cl. H03M 13/13; H03M 13/11; H04L 1/00

(52) U.S. Cl. CPC H03M 13/13; H03M 13/1125; H04L 1/0057

(57) ABSTRACT

Provided are a wireless communication terminal, a method of decoding a polar code, and a decoding module. The wireless communication terminal includes first and second antennas configured to respectively receive one signal transmitted from a transmitting-side device via different channels, a communication module configured to output first and second reception codewords by performing digital conversion on the signals respectively received through the first and second antennas and demodulating the signals, and a processor configured to combine log likelihood ratio (LLR) values of the first and second reception codewords with each other and sequentially perform successive cancellation (SC) decoding (SCD) bit by bit using a combined LLR value for estimating a next LLR value.

### CROSS-REFERENCE TO RELATED APPLICATIONS

This application claims priority to and the benefit of Korean Patent Applications No. 10-2024-0108874, filed on Aug. 14, 2024, and No. 10-2025-0064059, filed on May 16, 2025, the disclosure of which is incorporated herein by reference in its entirety.

### BACKGROUND

### 1. Field of the Invention

Various exemplary embodiments disclosed in the present document relate to a data encoding and decoding technology.

### 2. Description of Related Art

In general, when data is transmitted and received between a transmitter and a receiver in a communication system, data errors may occur due to noise present in the communication channel. Error correction code techniques (or channel coding) designed for a transmitter to process an error that occurs in such a communication channel are applied.

Among the error correction code techniques, polar codes are channel codes that utilize a phenomenon called channel polarization to achieve a channel capacity in a simple and effective way. When encoding with a structured generator matrix and successive cancellation (SC) decoding (SCD) are used in a process of transmitting a plurality of bits through each bit channels, a channel for each bit is transformed into a virtual polarized synthesized channel. In this process, some synthesized channels become excellent channels with a channel capacity close to the maximum (1), while other synthesized channels become poor channels with a channel capacity close to the minimum (0).

The total sum of channel capacities of the synthesized channels remains the same before and after the transformation. Also, since channel polarization is maximized with an increase in code length, excellent channels have a channel capacity of 1, and poor channels have a channel capacity of 0. Therefore, a transmitter may theoretically achieve a channel capacity for a given channel easily and effectively by transmitting bits of information to be transmitted on good channels and assigning frozen bits to bad channels.

In 3^{rd} Generation Partnership Project (3GPP) Fifth Generation (5G) New Radio (NR) systems, low density parity check (LDPC) codes are adopted for data channels (physical downlink shared channels (PDSCHs) and physical uplink shared channels (PUSCHs)) as a channel coding scheme, and polar codes are adopted as standard technology for control channels (physical downlink control channels (PDCCHs)) and broadcast channels (physical broadcast channels (PBCHs)).

Specifically, broadcast channels (PBCHs) have short data and have to be decoded within a short time, and thus it is necessary to use channel coding with low decoding complexity. Also, since control channels are transmitted using a blind decoding scheme, it is necessary to repeatedly decode using a space of candidate radio resources in which the control channels may be transmitted, which requires fast decoding with low complexity to lower power consumption of a terminal. For this reason, broadcast channels and control channels of 3GPP 5G NR systems are coded using polar codes that are rapidly encodable and decodable with low complexity.

Polar codes are characterized by being encoded to obtain a gain of channel coding using the channel polarization phenomenon. Channel polarization is a phenomenon in which a recovery probability of error in a wireless channel becomes very large or a very small depending on an input position of an encoder. The magnitude of channel polarization may be expressed as a mutual information value. Generally, in polar codes, fixed bits (or frozen bits) that both a sender and a receiver know are mapped to bit positions with very small mutual information values, and information bits are input to positions with large mutual information values and transmitted.

Channel codes are classified as systematic codes and non-systematic codes, and 3GPP 5G NR systems have adopted non-systematic polar codes as standard technology.

### SUMMARY OF THE INVENTION

Since a control channel that is coded using a polar code transmits information required for data reception, it is necessary to transmit the control channel before a data channel and maintain high reliability. However, in a situation with a poor wireless channel, reliability of control channels is degraded, and thus a technology for improving reliability of control channels is required.

Various embodiments disclosed in the present document may provide a wireless communication terminal for decoding a systematic polar code transmitted via a multi-antenna channel, an encoding module, a decoding module, and a method of decoding the polar code.

According to an embodiment disclosed in the present document, there is provided a wireless communication terminal including first and second antennas configured to respectively receive signals transmitted from a transmitting-side device via different channels, a communication module configured to output first and second reception codewords by performing digital conversion on the signals respectively received through the first and second antennas and demodulating the signals, and a processor configured to combine log likelihood ratio (LLR) values of the first and second reception codewords with each other and sequentially perform successive cancellation (SC) decoding (SCD) bit by bit using a combined LLR value for estimating a next LLR value.

According to an embodiment disclosed in the present document, there is provided a method of decoding a polar code by at least one processor, the method including respectively receiving, by first and second antennas, signals transmitted from a transmitting-side device via different channels, performing digital conversion on the signals respectively received through the first and second antennas and demodulating the signals to acquire first and second reception codewords, and combining LLR values of the first and second reception codewords with each other and then sequentially performing SCD bit by bit using a combined LLR value for estimating a next LLR value.

According to another embodiment disclosed in the present document, there is provided a decoding module including a first estimation block and a second estimation block configured to sequentially estimate a first LLR value and a second LLR value in order of designated turns for first and second reception codewords acquired via different channels, and a combination block configured to combine the first and second LLR values with each other and estimate a value of each turn on the basis of the combined value. The first and second estimation blocks estimate a next LLR value using a bit value estimated by the combination block.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a diagram showing a structure of a polar encoder when N equals 2 and when N equals 4;

FIG. 2 is a diagram of a non-systematic polar encoder with a bit length of 4;

FIG. 3 is a diagram of a systematic polar encoder;

FIG. 4 is a diagram of polar encoders and decoders of a terminal at two transmission points;

FIG. 5 is a block diagram of a wireless communication terminal according to an exemplary embodiment;

FIG. 6 is a diagram related to decoding of a wireless communication terminal (500) according to an exemplary embodiment;

FIG. 7 is a detailed diagram of a decoder module according to an exemplary embodiment;

FIGS. 8 and 9 are graphs comparatively showing bit error rate (BER) and frame error rate (FER) performance of a successive cancellation (SC) decoding (SCD) technique according to an exemplary embodiment and another SCD technique in accordance with the number of antennas, whether log likelihood ratios (LLRs) of multiple antennas are combined, and a channel environment; and

FIG. 10 is a flowchart of a method of decoding a polar code according to an exemplary embodiment.

In relation to the description of drawings, like reference numerals may be used for like components.

### DETAILED DESCRIPTION OF EXEMPLARY EMBODIMENTS

Polar codes have been proposed as non-systematic codes, but they are linear block codes and thus may be changed into systematic codes. In other words, when a matrix multiplication (linear transformation) is performed on F^{⊗n} and a codeword, an inverse function of F^{⊗n} is F^{⊗n}, that is, itself.

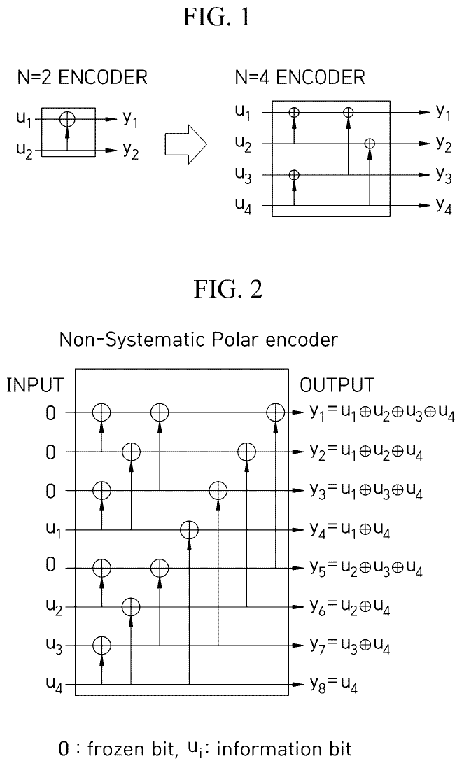

FIG. 1 is a diagram showing a structure of a polar encoder when N is 2 and when N is 4. Here, N is a codeword length which equals 2ⁿ, and n is a natural number. [N=2, 4, 8, 16, 32, . . . ]

Referring to FIG. 1, a polar encoder has a structure beginning with an encoding matrix (210 of FIG. 2) with N equal to 2, and the structure is recursively extended.

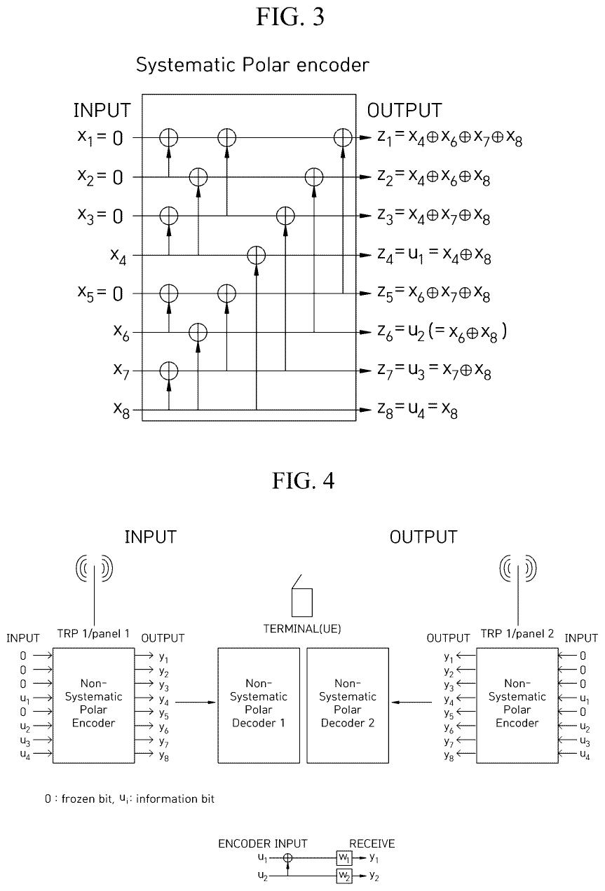

FIG. 2 is a diagram of a non-systematic polar encoder with a bit length of 4, and FIG. 3 is a diagram of a systematic polar encoder with a bit length of 4.

Referring to FIG. 2, the non-systematic polar encoder and the systematic polar encoder that encode an input {u₁, u₂, u₃, u₄} with an input (information) bit length of 4 also have a structure extended from the structure with N equal to 2.

Referring to FIG. 2, the non-systematic polar encoder performs encoding by inputting information bits to be transmitted and inputting fixed bits which are determined values at positions promised between a transmitter and a receiver. FIG. 2 shows an example with a codeword length equal to 8 (N=8). A polarization process of the non-systematic polar encoder may be expressed as follows.

$$\begin{matrix}[ {y}_{1} & {y}_{2} & {y}_{3} & {y}_{4} & {y}_{5} & {y}_{6} & {y}_{7} & {y}_{8} ]\end{matrix} = \begin{matrix}[ 0 & 0 & 0 & {u}_{1} & 0 & {u}_{2} & {u}_{3} & {u}_{4} ]\end{matrix} [ \begin{matrix}1 & 0 & 0 & 0 & 0 & 0 & 0 & 0 \\ 1 & 1 & 0 & 0 & 0 & 0 & 0 & 0 \\ 1 & 0 & 1 & 0 & 0 & 0 & 0 & 0 \\ 1 & 1 & 1 & 1 & 0 & 0 & 0 & 0 \\ 1 & 0 & 0 & 0 & 1 & 0 & 0 & 0 \\ 1 & 1 & 0 & 0 & 1 & 1 & 0 & 0 \\ 1 & 0 & 1 & 0 & 1 & 0 & 1 & 0 \\ 1 & 1 & 1 & 1 & 1 & 1 & 1 & 1\end{matrix} ] = d \cdot {F}^{⊗ n} \qquad [ Expression 1 ]$$

$$F = [ \begin{matrix}1 & 0 \\ 1 & 1\end{matrix} ] , n = 3 , d = \begin{matrix}[ {d}_{1} & {d}_{2} & {d}_{3} & {d}_{4} & {d}_{5} & {d}_{6} & {d}_{7} & {d}_{8} ]\end{matrix} = \begin{matrix}[ 0 & 0 & 0 & {u}_{1} & 0 & {u}_{2} & {u}_{3} & {u}_{4} ]\end{matrix} \qquad [ Expression 2 ]$$

n-log₂(N), F^{⊗n}=F⊗ . . . ⊗F(n Fs), n-fold Kronecker product

The non-systematic polar encoder receives the 4 information bits “u₁, u₂, u₃, u₄” to be transmitted and the 4 fixed bits (frozen bits equal to 0) and encodes the received bits. A codeword which is a set of output bits of the non-systematic polar encoder is {y₁, y₂, y₃, y₄, y₅, y₆, y₇, y₈}. Here, ⊕ is an exclusive OR (XOR) operation and may be an F^{⊗n} transform operation.

Referring to FIG. 3, the systematic polar encoder receives fixed bits (frozen bits) {0, 0, 0, 0} and bits {x₄, x₆, x₇, x₈} calculated from information bits and encodes the received bits to output information bits {u₁ (=z₄), u₂ (=z₆), u₃ (=z₇), u₄ (=z₈)} and parity bits {z₁, z₂, z₃, z₅}. The systematic polar encoder may be expressed as follows.

$$\begin{matrix}[ {z}_{1} & {z}_{2} & {z}_{3} & {z}_{4} & {z}_{5} & {z}_{6} & {z}_{7} & {z}_{8} ]\end{matrix} = [ \begin{matrix}0 & 0 & 0 & {x}_{4} & 0 & {x}_{6} & {x}_{7} & {x}_{8}\end{matrix} ] [ \begin{matrix}1 & 0 & 0 & 0 & 0 & 0 & 0 & 0 \\ 1 & 1 & 0 & 0 & 0 & 0 & 0 & 0 \\ 1 & 0 & 1 & 0 & 0 & 0 & 0 & 0 \\ 1 & 1 & 1 & 1 & 0 & 0 & 0 & 0 \\ 1 & 0 & 0 & 0 & 1 & 0 & 0 & 0 \\ 1 & 1 & 0 & 0 & 1 & 1 & 0 & 0 \\ 1 & 0 & 1 & 0 & 1 & 0 & 1 & 0 \\ 1 & 1 & 1 & 1 & 1 & 1 & 1 & 1\end{matrix} ] = x \cdot {F}^{⊗ n} \qquad [ Expression 3 ]$$

$$x = [ \begin{matrix}{x}_{1} & {x}_{2} & {x}_{3} & {x}_{4} & {x}_{5} & {x}_{6} & {x}_{7} & {x}_{8}\end{matrix} ] \qquad [ Expression 4 ]$$

Since the inverse function of F^{⊗n} is Fon, that is, itself, systematic polar encoding may be performed using x=z·F^{⊗n}.

In the case of transmitting a physical broadcast channel (PBCH) and a physical downlink control channel (PDCCH) using multiple antennas or multiple transmission points/panels of 5G NR, a polar code is encoded in the same way and transmitted to each transmission point/panel. Here, the polar encoder operates in a non-systematic manner.

FIG. 4 is a diagram of polar encoders and decoders of a terminal at two transmission points. FIG. 4 is an example in which the two transmission points perform non-systematic polar encoding and transmit signals and the terminal decodes the signals received from the two transmission points using two polar decoders.

Referring to FIG. 4, the encoders encode 4 input information bits and 4 frozen bits, and encoded bits (parity bits) y₁, y₂, y₃, y₄, y₅, y₆, y₇, and y₈ are received as 8 bits y₁′, y₂′, y₃′, y₄′, y₅′, y₆′, y₇′, and y₈′ by the terminal via wireless channels and then input to the polar decoders. When the bits are decoded without any error at the polar decoders, the polar decoders output 0, 0, 0, u₁′, 0, u₂′, u₃′, and u₄′.

Bit error rate (BER) performance of systematic polar code encoding is better than that of non-systematic polar code encoding, but block error rates (BLERs) are almost the same.

Since a polar code with a codeword length of N has a structure of N equal to 2 which expands recursively to, a decoder of a polar code may perform decoding by recursively repeating an operation with a structure of N equal to 2. When decoding is performed using successive cancellation (SC) decoding (SCD), in the case of a polar code with a codeword length of N equal to 2, the decoder estimates the bits u₁ and u₂ through the following operation.

For example, the two bits u₁ and u₂ may be input to an encoder at a transmitting end, and two bits y₁ and y₂ may be received at a receiving end. In this case, when channels are W₁ and W₂ and LLR values of y₁ and y₂ estimated at the receiving end are L₁ and L₂, the decoder may calculate L₁ and L₂ which are the LLR values of y₁ and y₂ to estimate W⁻(L₁, L₂) as the fixed bit u₁, and may estimate W⁺(L₁, L₂, u₁) as u₂ using L₁, L₂, and u₁.

$${W}^{-} ( {y}_{1} , {y}_{2} \vert {u}_{1} ) = \frac{1}{2} {\sum }_{{u}_{2}} {w}_{1} ( {y}_{1} \vert {u}_{1} ⊕ {u}_{2} ) {w}_{2} ( {y}_{2} \vert {u}_{2} ) , {W}^{-} ( {L}_{1} , {L}_{2} ) = log ( \frac{1 + {e}^{{L}_{1} + {L}_{2}}}{{e}^{{L}_{1}} + {e}^{{L}_{2}}} ) \qquad [ Expression 5 ]$$

$${W}^{+} ( {y}_{1} , {y}_{2} , {u}_{1} \vert {u}_{2} ) = \frac{1}{2} {w}_{1} ( {y}_{1} \vert {u}_{1} ⊕ {u}_{2} ) {w}_{2} ( {y}_{2} \vert {u}_{2} ) , {W}^{+} ( {L}_{1} , {L}_{2} , {u}_{1} ) = {( - 1 )}^{{u}_{1}} {L}_{1} + {L}_{2} \qquad [ Expression 6 ]$$

In other words, when N equals 2, the LLR values L₁ and L₂ are calculated from the received two bits y₁ and y₂ to estimate the bit u₁, and the bit u₂ is estimated from u₁, L₁, and L₂.

When N equals 4, an encoder acquires u₁, u₂, u₃, and u₄ as inputs, and the terminal receives y₁, y₂, y₃, and y₄ to sequentially calculate LLR values for the four bits and estimate the bits. In other words, LLR values L₁ and L₃ are calculated from the received y₁, y₂, y₃, and y₄ to estimate the bit u₁, and the bit u₃ is estimated from u₁, L₁, and L₃. Subsequently, L₂ and L₄ are calculated to estimate the bit u₂, and the bit u₄ is estimated from u₂, L₂, and L₄.

Referring to FIGS. 2 to 4, non-systematic polar codes indirectly contain information bits, while systematic polar codes directly contain information bits.

Meanwhile, by transmitting the same signal through multiple antennas in a communication system, even when one antenna fails to transmit or receive the signal, other antennas may still be used to transmit or receive the signal, thus improving communication channel coding performance,

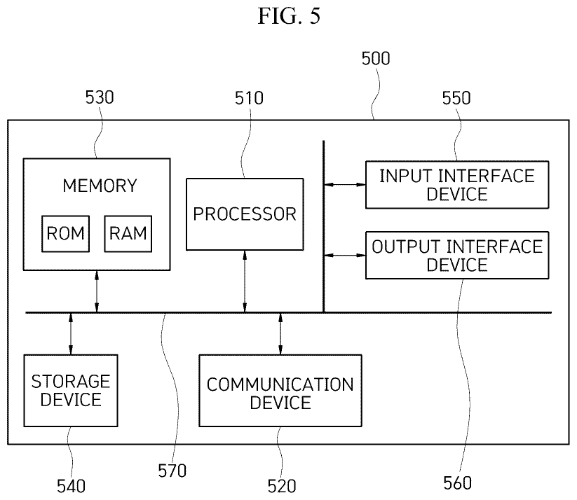

FIG. 5 is a block diagram of a wireless communication terminal according to an exemplary embodiment.

Referring to FIG. 5, a wireless communication terminal 500 may include at least one of a processor 510, a memory 530, an input interface device 550, an output interface device 560, and a storage device 540 that communicate through a bus 570. The wireless communication terminal 500 may further include a communication device 520 connected to a network. The processor 510 may be a central processing unit (CPU) or a semiconductor device that executes commands stored in the memory 530 or the storage device 540. The memory 530 and the storage device 540 may include various forms of volatile or non-volatile storage media. For example, the memory 530 may include a read-only memory (ROM) and a random-access memory (RAM). In exemplary embodiments of the present document, the memory 530 may be inside or outside of the processor 510, and the memory 530 may be connected to the processor 510 through various known devices.

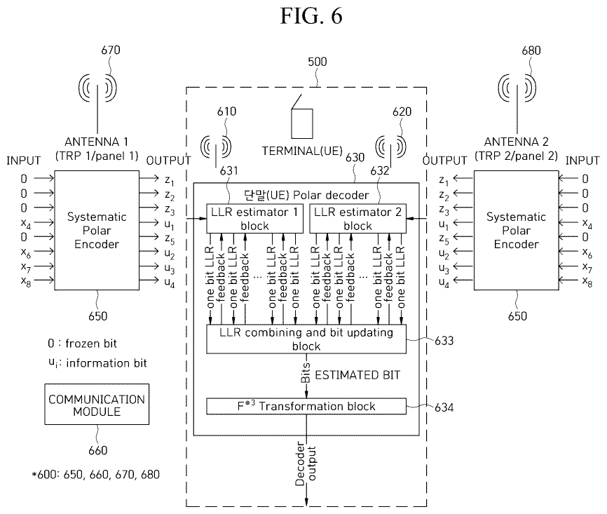

FIG. 6 is a diagram of a wireless communication terminal 500 related to decoding according to an exemplary embodiment.

Referring to FIG. 6, a transmitting-side device 600 according to an exemplary embodiment may include a polar code encoder 650, a communication module 660, and first and second transmission antennas 670 and 680. According to the embodiment, the transmitting-side device 600 is a transmitting-side device of a 3^{rd} Generation Partnership Project (3GPP) Fifth Generation (5G) New Radio (NR) system and may be, for example, a base station device.

The polar code encoder 650 may be, for example, an encoder with a code rate of 1/2. The polar code encoder 650 may generate a codeword by encoding a transmission bitstring including information bits and fixed bits as a systematic polar code. In this regard, the information bits may have information with bit values of 0 or 1 and may be assigned to a sub-channel with high channel capacity in the polar code. The fixed bits have fixed values and may be assigned to a sub-channel with low channel capacity. Fixed bits are generally determined to be 0 but are not necessarily limited thereto (i.e., a value of a fixed bit may be determined to be 1). These fixed bits are used for channel polarization and may increase channel capacity of another sub-channel in return for the amount of information given up by fixing the bits.

When bits {x₄, x₆, x₇, x₈} calculated from fixed bits {0, 0, 0, 0} and information bits are input and encoded, the polar code encoder 650 may generate a codeword including coded information bits {u₁, u₂, u₃, u₄} and parity bits {z₁, z₂, z₃, z₅}. In this regard, the parity bits in the polar code are causally generated on the basis of preceding bits (bits with smaller indexes).

The communication module 660 may modulate the codeword, convert the modulated codeword into a signal in the radio frequency (RF) band, and transmit the RF signal to each of the first and second transmission antennas 670 and 680.

The first and second transmission antennas 670 and 680 may transmit the same codeword via different channels.

Referring to FIG. 6, the wireless communication terminal 500 according to the exemplary embodiment may further include first and second antennas 610 and 620 and a decoding module 630.

Each of the first and second antennas 610 and 620 may receive a signal containing information bits {u₁, u₂, u₃, u₄} and parity bits {z₁, z₂, z₃, z₅} multiplexed and transmitted by the transmitting-side device 600. For example, the first antenna 610 may receive a signal transmitted via the first transmission antenna 670, and the second antenna 620 may receive a signal transmitted via the second transmission antenna 680.

The communication device 520 may remove carrier waves from the signals received by the first antenna 610 and the second antenna 620 and demodulate the signals to output a first reception codeword and a second reception codeword which have been analog-to-digital converted. The first and second reception codewords may be received via different channels (a first channel in accordance with the first transmission antenna 670 and the first antenna 610 and a second channel in accordance with the second transmission antenna 680 and the second antenna 620) but may include information bits.

The decoding module 630 may perform SC-based decoding on the first and second reception codewords. For example, the decoding module 630 may be a part of the processor 510 or may be provided as a separate device from the processor 510.

According to the exemplary embodiment, the decoding module 630 may include a first estimation block 631, a second estimation block 632, a combination block 633, and a transformation block 634.

Each of the first and second estimation blocks 631 and 632 is an LLR estimation block and calculates an LLR value which is a possibility-based metric on the basis of input bits and a previous estimation value. The LLR value may be a possibility value that each bit will be a specific bit (0 or 1).

The first and second estimation blocks 631 and 632 may estimate first and second LLR values sequentially bit by bit in order of designated turns on the basis of the first and second codewords received via the first antenna 610 and the second antenna 620. For example, the first estimation block 631 may sequentially estimate a first LLR value for a bit of each turn bit by bit in order of designated turns on the basis of the first reception codeword. Also, the second estimation block 632 may sequentially estimate a second LLR value for a bit of each turn bit by bit in order of designated turns on the basis of the second reception codeword. The designated turns are determined in accordance with an SCD tree structure and may differ from indexes of the first and second reception codewords.

In addition, each of the first and second estimation blocks 631 and 632 may estimate an LLR value for a bit of a next turn using an LLR value for a bit of a previous turn and a bit value (at least one bit value estimated at previous turn) of the previous turn fed back from the combination block 633.

The combination block 633 may acquire a first LLR value and a second LLR value of the same turn from the first estimation block 631 and the second estimation block 632. The combination block 633 may combine the acquired first and second LLR values with each other and sequentially estimate a bit value of each turn on the basis of a combined bit value. For example, the combination block 633 may combine the first and second LLR values in accordance with a designated formula (e.g., by adding them together) to sequentially estimate a bit value of each turn.

The combination block 633 may share (feedback) estimated bit values bit by bit to the first and second estimation blocks 631 and 632. Here, the estimated bit values may be values used for decoding recursive construction of a polar code. For example, when N equals 2, the combination block 633 may calculate a bit value u₁ of each turn by combining a first LLR value L₁ and a second LLR value L₂ and share the bit value u₁ with the first and second estimation blocks 631 and 632. Each of the first and second estimation blocks 631 and 632 may calculate an LLR value for a bit value of a next turn as u₂ [W⁺(L₁, L₂, u₁)=(−1)^{u}^{₁}L₁+L₂] using the shared bit value u₁ of the previous turn. According to the exemplary embodiment, a case where the decoding module 630 sequentially calculates the bits u₁ and u₂ has been described as an example. However, embodiments are not limited thereto.

When bit values of all turns are estimated, the combination block 633 may transmit an estimated bit set to the transformation block 634.

The transformation block 634 may estimate information bits by performing a matrix multiplication on the estimated bit set \hat{x}=[\hat{x}₁ \hat{x}₂ \hat{x}₃ \hat{x}₄ \hat{x}₅ \hat{x}₆\hat{x}₇\hat{x}₈] with F^{⊗n} F is referred to as a polarization kernel, and the superscript ⊗n is an nth Kronecker power. When the number of bits to be estimated is 4,

$${F}^{⊗ 3} = [ \begin{matrix}1 & 0 & 0 & 0 & 0 & 0 & 0 & 0 \\ 1 & 1 & 0 & 0 & 0 & 0 & 0 & 0 \\ 1 & 0 & 1 & 0 & 0 & 0 & 0 & 0 \\ 1 & 1 & 1 & 1 & 0 & 0 & 0 & 0 \\ 1 & 0 & 0 & 0 & 1 & 0 & 0 & 0 \\ 1 & 1 & 0 & 0 & 1 & 1 & 0 & 0 \\ 1 & 0 & 1 & 0 & 1 & 0 & 1 & 0 \\ 1 & 1 & 1 & 1 & 1 & 1 & 1 & 1\end{matrix} ]$$

may hold.

$$[ \begin{matrix}{\hat{x}}_{1} & {\hat{x}}_{2} & {\hat{x}}_{3} & {\hat{x}}_{4} & {\hat{x}}_{5} & {\hat{x}}_{6} & {\hat{x}}_{7} & {\hat{x}}_{8}\end{matrix} ] [ \begin{matrix}1 & 1 & 0 & 0 & 0 & 0 & 0 & 0 \\ 1 & 0 & 1 & 0 & 0 & 0 & 0 & 0 \\ 1 & 1 & 1 & 1 & 0 & 0 & 0 & 0 \\ 1 & 0 & 0 & 0 & 1 & 0 & 0 & 0 \\ 1 & 1 & 0 & 0 & 1 & 1 & 0 & 0 \\ 1 & 0 & 1 & 0 & 1 & 0 & 1 & 0\end{matrix} ] \qquad [ Expression 7 ]$$

As described above, the transformation block 634 may obtain fixed bits and information bits using Expression 7.

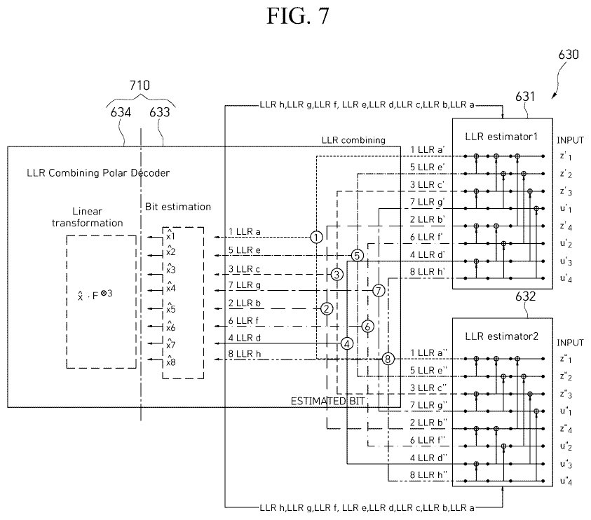

FIG. 7 is a detailed diagram of a decoder module according to an exemplary embodiment. FIG. 7 illustrates a case in which a codeword length N equals 8, the first and second estimation blocks 631 and 632 calculate an LLR value of each bit on the basis of the first and second codewords received via the first antenna 610 and the second antenna 620. And the combination block 633 and the transformation block 634 are included in an LLR combining polar decoder 710.

The first estimation block 631 may acquire z₁′, z₂′, z₃′, u₁′, z₄′, u₂′, u₃′, and u₄′ of the signal received via the first antenna 610 as inputs. The second estimation block 632 may acquire z₁″, z₂″, z₃″, u₁″, z₄″, u₂″, u₃″, and u₄″ of the signal received via the second antenna 620 as inputs. The first and second estimation blocks 631 and 632 may estimate an LLR in a designated order in accordance with a polar tree structure. According to the exemplary embodiment, a case where LLR estimation and bit estimation are performed in order of x₁→x₅→x₃→x₇→x₂→x₆→x₄→x₈ is described as an example. However, embodiments are not limited thereto.

First, the first estimation block 631 calculates a first bit LLR a′ (an LLR value for estimating x₁ transmitted from the transmitting side) and transmits the first bit LLR a′ to the LLR combining polar decoder 710. The second estimation block 632 calculates a first bit LLR a″ (an LLR value for estimating x₁ transmitted from the transmitting side) and transmits the first bit LLR a″ to the LLR combining polar decoder 710.

The LLR combining polar decoder 710 may estimate a value \hat{x}₁ obtained by combining LLR a′ and LLR a″ as the first bit x₁ transmitted from the transmitting side. The LLR combining polar decoder 710 feeds back (shares) the estimated value to the first estimation block 631 and the second estimation block 632 such that the estimated value \hat{x}₁ may be used for calculating an LLR value for a next bit.

Subsequently, the first estimation block 631 calculates LLR b′ (an LLR value for the first estimation block 631 to estimate x₅ transmitted from the transmitting side) and transmits LLR b′ to the LLR combining polar decoder 710, and the second estimation block 632 calculates LLR b″ (an LLR value for the second estimation block 632 to estimate x₅ transmitted from the transmitting side) and transmits LLR b″ to the LLR combining polar decoder 710.

The LLR combining polar decoder 710 estimates x₅ (Hereinafter, referred to \hat{x}₅′) obtained by combining LLR b′ and LLR b″ and feeds back (shares) the estimated value x₅ to the first estimation block 631 and the second estimation block 632 such that the estimated value \hat{x}₅ may be used for calculating an LLR value for a next bit.

Subsequently, the first estimation block 631 calculates LLR c′ which is an LLR value for estimating x₃ transmitted from the transmitting side, and transmits LLR c′ to the LLR combining polar decoder 710, and the second estimation block 632 calculates LLR c″ which is an LLR value for estimating x₃ transmitted from the transmitting side, and transmits LLR c″ to the LLR combining polar decoder 710.

The LLR combining polar decoder 710 estimates x₃ to be a value \hat{x}₃ obtained by combining LLR c′ and LLR c″ and feeds back (shares) the estimated value x₃ to the first estimation block 631 and the second estimation block 632 such that the estimated value may be used for calculating an LLR value for a next bit.

Subsequently, the first estimation block 631 calculates LLR d′ which is an LLR value for estimating x₇ transmitted from the transmitting side, and transmits LLR d′ to the LLR combining polar decoder 710, and the second estimation block 632 calculates LLR d″ which is an LLR value for estimating x₇ transmitted from the transmitting side, and transmits LLR d″ to the LLR combining polar decoder 710.

The LLR combining polar decoder 710 estimates x₇ (Hereinafter, referred to \hat{x}₇′ obtained by combining LLR d′ and LLR d″ and feeds back (shares) the estimated value \hat{x}₇ to the first estimation block 631 and the second estimation block 632 such that the estimated value may be used for calculating an LLR value for a next bit.

Subsequently, the first estimation block 631 calculates LLR e′ which is an LLR value for estimating x₂ transmitted from the transmitting side, and transmits LLR e′ to the LLR combining polar decoder 710, and the second estimation block 632 calculates LLR e″ which is an LLR value for estimating x₂ transmitted from the transmitting side, and transmits LLR e″ to the LLR combining polar decoder 710.

The LLR combining polar decoder 710 estimates x₂ \hat{x}₇′ \hat{x}₂ obtained by combining LLR e′ and LLR e″ and feeds back (shares) the estimated value to the first estimation block 631 and the second estimation block 632 such that the estimated value may be used for calculating an LLR value for a next bit.

Subsequently, the first estimation block 631 calculates LLR f which is an LLR value for estimating x₆ transmitted from the transmitting side, and transmits LLR f to the LLR combining polar decoder 710, and the second estimation block 632 calculates LLR f′ which is an LLR value for estimating x₆ transmitted from the transmitting side, and transmits LLR f″ to the LLR combining polar decoder 710.

The LLR combining polar decoder 710 estimates x₆ (Hereinafter, referred to a value \hat{x}₆) obtained by combining LLR f′ and LLR f′ and feeds back (shares) the estimated value \hat{x}₆ to the first estimation block 631 and the second estimation block 632 such that the estimated value may be used for calculating an LLR value for a next bit.

Subsequently, the first estimation block 631 calculates LLR g′ (an LLR value for estimating x₄ transmitted from the transmitting side) and transmits LLR g′ to the LLR combining polar decoder 710, and the second estimation block 632 calculates LLR g″ (an LLR value for estimating x₄ transmitted from the transmitting side) and transmits LLR g″ to the LLR combining polar decoder 710.

The LLR combining polar decoder 710 estimates x₄ (Hereinafter, referred to \hat{x}₄) obtained by combining LLR g′ and LLR g″ and feeds back (shares) the estimated value \hat{x}₄ to the first estimation block 631 and the second estimation block 632 such that the estimated value may be used for calculating an LLR value for a next bit.

Subsequently, the first estimation block 631 calculates LLR h′ (an LLR value for estimating x₈ transmitted from the transmitting side) and inputs LLR h′ to the LLR combining polar decoder 710, and the second estimation block 632 calculates LLR h″ (an LLR value for estimating x₈ transmitted from the transmitting side) and inputs LLR h″ to the LLR combining polar decoder 710.

The LLR combining polar decoder 710 estimates x₈ (Hereinafter, referred to \hat{x}₈) obtained by combining LLR h′ and LLR h″ and feeds back (shares) the estimated value to the first estimation block 631 and the second estimation block 632 such that the estimated value may be used for calculating an LLR value for a next bit.

When a string of all the 8 bits is estimated, the LLR combining polar decoder 710 inputs a set \hat{x} of the estimated bits to the transformation block 634. The transformation block 634 may estimate transmitted information bits to

be a result of a matrix multiplication between the set of the estimated bits \hat{x}=[\hat{x}₁ \hat{x}₂ \hat{x}₃ \hat{x}₄ \hat{x}₅ \hat{x}₆\hat{x}₇\hat{x}₈] and F^{⊗n}.

The above-described embodiment illustrates a case where the transmitting-side device 600 and a receiving-side device (e.g., 500) transmit and receive a signal using two antennas. However, embodiments are not limited thereto. For example, the transmitting-side device 600 may transmit signals containing the same information bits or different information bits using one antenna or three or more antennas. Also, the wireless communication terminal 500 may separately receive the transmitted signals using three or more antennas. However, even in this case, the wireless communication terminal 500 may combine codewords received via different channels using signals received by a plurality of antennas among the three or more antennas, thereby performing decoding.

As described above, the wireless communication terminal 500 according to the exemplary embodiment receives signals, which are encoded as polar codes and transmitted via a plurality of channels, using a plurality of antennas, estimates each bit value by combining the signals received by the antennas with each other, and uses the estimated bit value for estimating a next bit. Accordingly, when a communication error occurs in one channel, the error can be corrected on the basis of a received signal of another channel. Therefore, it is possible to improve decoding reliability, and thus communication reliability can be improved.

In addition, the wireless communication terminal 500 according to the exemplary embodiment improves decoding performance of polar codes that are applied to a control channel including information related to a data channel receiving method. Accordingly, it is possible to improve communication stability and reliability of data that is decoded on the basis of information of a control channel.

Further, the wireless communication terminal 500 according to the exemplary embodiment uses systematic polar codes directly containing information bits for encoding and decoding. Accordingly, it is possible to improve BER performance compared to existing systematic polar codes, and easily support post-decoding verification.

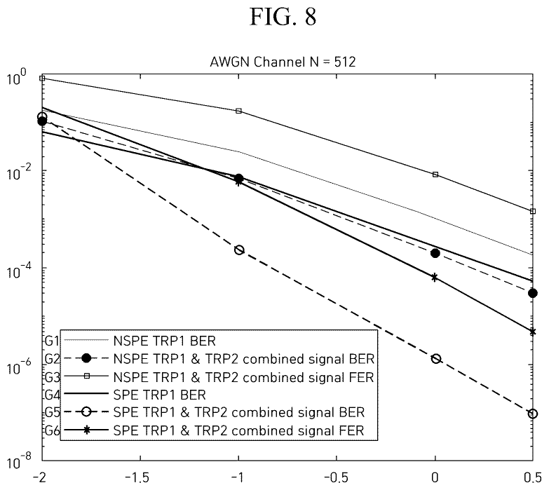

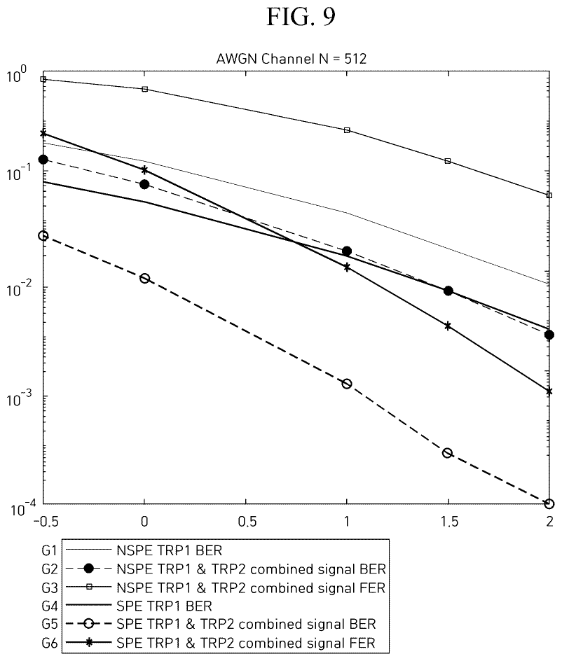

FIGS. 8 and 9 are graphs comparatively showing BER and frame error rate (FER) performance of an SCD technique according to an exemplary embodiment and another SCD technique in accordance with the number of antennas, whether LLRs of multiple antennas are combined, and a channel environment. FIG. 8 may be a case where a codeword length of N equal to 512 is applied to an additive white Gaussian noise (AWGN) channel, and FIG. 9 may be a case where a codeword length of N equal to 256 is applied to a Rayleigh channel.

In FIGS. 8 and 9, a first graph G1 obtained by applying a non-systematic polar encoding (NPSE) technique to a transmitting side may show BER performance of a case of performing SCD on a signal received by a single antenna, and a second graph G2 and a third graph G3 may show BER and FER performance of a case of performing SCD by combining LLR values for signals received via multiple antennas without information exchange.

Similarly, fourth to sixth graphs (G4 to G6) are graphs corresponding to SCD techniques according to exemplary embodiments in which systematic polar encoding (SPE) is applied to a transmitting side. The fourth graph G4 may show BER performance of a case of performing SCD on a signal received by a single antenna, and a fifth graph G5 and a sixth graph G6 may show BER and FER performance of a case of performing SCD by calculating LLR values bit by bit for signals received via multiple antennas, combining the LLR values, and reflecting the combined value in calculating LLR values of other bits. Performance of the above-described embodiment may be, for example, the fifth and sixth graphs G5 and G6.

In FIGS. 8 and 9, irrespective of a codeword length, SCD techniques according to the exemplary embodiments show better performance than SCD techniques according to the related art in terms of BER and FER in not only a wired channel (the AWGN channel) but also a wireless channel (the Rayleigh channel).

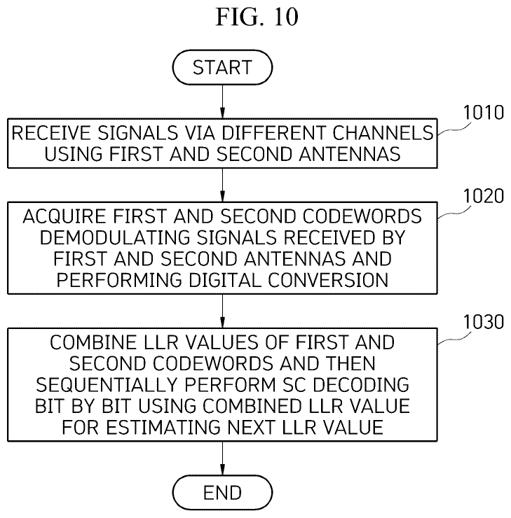

FIG. 10 is a flowchart of a method of decoding a polar code according to an exemplary embodiment.

Referring to FIG. 10, in operation 1010, the wireless communication terminal 500 may receive signals transmitted from a transmitting-side device via different channels using first and second antennas. The signals may be encoded systematic polar code by the transmitting-side device.

In operation 1020, the wireless communication terminal 500 may acquire first and second reception codewords by performing digital conversion on the signals respectively received through the first and second antennas and demodulating the signals.

In operation 1030, the wireless communication terminal 500 may combine LLR values of the first and second reception codewords with each other and sequentially perform SCD in order of designated turns using a combined LLR value for estimating a next LLR value. For example, the wireless communication terminal 500 may sequentially estimate LLR values of the first reception codeword bit by bit in order of designated turns and sequentially estimate LLR values of the second reception codeword in order of designated turns. The wireless communication terminal 500 may combine respectively estimated LLR values of each turn and sequentially estimate a bit value of each turn on the basis of a combined bit value. During this process, the wireless communication terminal 500 may share each estimated bit value with the first and second estimation blocks and estimate LLR values of a next turn from the first and second reception codewords on the basis of the shared bit value and a bit value of the next turn.

Subsequently, when bit values of all the turns of the first and second codewords are estimated, the wireless communication terminal 500 may output a set of the estimated bits in parallel and acquire fixed bits and information bits by performing a matrix multiplication on the set of the bits and F^{⊗n} (n=log₂N).

As described above, the wireless communication terminal 500 according to the exemplary embodiment receives signals, which are encoded as polar codes and transmitted via a plurality of channels, using a plurality of antennas, estimates each bit value by combining the signals received by the antennas with each other, and uses the estimated bit value for estimating a next bit. Accordingly, when a communication error occurs in one channel, the error can be corrected on the basis of a received signal of another channel. Therefore, it is possible to improve decoding reliability, and thus communication reliability can be improved.

In addition, the wireless communication terminal 500 according to the exemplary embodiment improves decoding performance of polar codes that are applied to a control channel including information related to a data channel receiving method. Accordingly, it is possible to improve communication stability and reliability of data that is decoded on the basis of information of a control channel.

Further, the wireless communication terminal 500 according to the exemplary embodiment uses systematic polar codes directly containing information bits for encoding and decoding. Accordingly, it is possible to improve BER performance compared to existing systematic polar codes, and easily support post-decoding verification.

It is to be understood that various embodiments of the present document and terms used in the embodiments are not intended to limit technological features set forth herein to specific embodiments and include various changes, equivalents, or substitutions for a corresponding embodiment. With regard to the description of the drawings, similar reference numerals may be used to refer to similar or related components. A singular form of a noun corresponding to an item may include one or more of the items unless the relevant context clearly indicates otherwise. As used herein, each of phrases such as “A or B,” “at least one of A and B,” “at least one of A or B,” “A, B, or C,” “at least one of A, B, and C,” and “at least one of A, B, or C” may include any one of or all possible combinations of items enumerated together in a corresponding one of the phrases. Terms such as “1^{st}” and “2^{nd}” or “first” and “second” may be used to simply distinguish a corresponding component from another, and do not limit the components in other aspects (e.g., importance or order). When a (e.g., first) component is referred to, with or without the term “functionally” or “communicatively,” as “coupled” or “connected” to another (e.g., second) component, it means that the first component may be coupled to the second component directly (e.g., by wire), wirelessly, or via a third component.

As used herein, the term “module” may include a unit implemented in hardware, software, or firmware, and may be interchangeably used with other terms, for example, “logic,” “logic block,” “part,” or “circuitry.” A module may be a single integral component or a minimum unit or part thereof that performs one or more functions. For example, according to an embodiment, a module may be implemented in the form of an application-specific integrated circuit (ASIC).

Various embodiments of the present document may be implemented as software (e.g., a program) including one or more instructions stored in a storage medium (e.g., an internal memory, an external memory, or the memory 530) that is readable by a machine (e.g., a wireless communication terminal). For example, a processor (e.g., the processor 510) of the machine (e.g., the wireless communication terminal 500) may invoke at least one of the one or more instructions stored in the storage medium and execute the at least one invoked instruction. This allows the machine to be operated to perform at least one function according to the at least one invoked instruction. The one or more instructions may include code generated by a compiler or code executable by an interpreter. The machine-readable storage medium may be provided in the form of a non-transitory storage medium. Here, the term “non-transitory” simply means that the storage medium is a tangible device, and does not include a signal (e.g., an electromagnetic wave), but this term does not distinguish between a case where data is semi-permanently stored in the storage medium and a case where data is temporarily stored in the storage medium.

According to an exemplary embodiment, a method according to various embodiments disclosed in the present document may be included and provided in a computer program product. The computer program product may be traded as a product between a seller and a buyer. The computer program product may be distributed in the form of a machine-readable storage medium (e.g., a compact disc (CD)-ROM) or distributed (e.g., downloaded or uploaded) online via an application store (e.g., Play Store™) or directly between two user devices (e.g., smartphones). When the computer program product is distributed online, at least a part of the computer program product may be temporarily generated or at least temporarily stored in the machine-readable storage medium, such as memory of the manufacturer's server, a server of the application store, or a relay server.

Components according to various embodiments of the present document may be implemented in the form of hardware such as a digital signal processor (DSP), a field programmable gate array (FPGA), or an ASIC and perform certain roles. Components are not limited to software or hardware, and each component may be configured to reside in an addressable storage medium or run on one or more processors. As an example, components may include components such as software components, object-oriented software components, class components, and task components, processes, functions, attributes, procedures, subroutines, segments of program code, drivers, firmware, microcode, circuitry, data, databases, data structures, tables, arrays, and variables.

According to various embodiments, each of the above-described components (e.g., modules or programs) may include a single entity or a plurality of entities. According to various embodiments, one or more of the above-described components or operations may be omitted, or one or more other components or operations may be added. Alternatively or additionally, a plurality of components (e.g., modules or programs) may be integrated into a single component. In this case, the integrated component may still perform one or more functions of the plurality of components in the same or similar manner as they are performed by the corresponding components among the plurality of components before the integration. According to various embodiments, operations performed by a module, a program, or another component may be carried out sequentially, in parallel, repeatedly, or heuristically, or at least one of the operations may be executed in a different order or omitted, or one or more other operations may be added.

According to various embodiments disclosed in the present document, it is possible to decode a systematic polar code transmitted via multiple channels.

In addition, according to various embodiments, in the case of transmitting a control channel via multiple channels such as antennas or the like, reliability of the control channel can be increased by performing systematic encoding on a transmitting side and combining signals received via the multiple channels to improve decoding performance.

What is claimed is:

1. A wireless communication terminal, comprising:
first and second antennas configured to respectively receive signals including same information transmitted from a transmitting-side device via different channels;
a communication module configured to output first and second reception codewords by performing digital conversion on respectively received signals respectively received through the first and second antennas and demodulating the signals; and
a processor configured to combine log likelihood ratio (LLR) values of the first and second reception codewords with each other and sequentially perform successive cancellation (SC) decoding (SCD) bit by bit using a combined LLR value for estimating a next LLR value.

2. The wireless communication terminal of claim 1, wherein the received signals are encoded using systematic polar code at the transmitting-side device.

3. The wireless communication terminal of claim 1, wherein the processor comprises:
a first estimation block configured to sequentially estimate LLR values of the first reception codeword in order of designated turns;
a second estimation block configured to sequentially estimate LLR values of the second reception codeword in order of designated turns; and
a combination block configured to combine LLR values of each turn respectively estimated by the first estimation block and the second estimation block and sequentially estimate a bit value of each turn on the basis of a combined bit value.

4. The wireless communication terminal of claim 3, wherein the combination block shares the estimated bit value with the first and second estimation blocks, and
the first and second estimation blocks estimate LLR values of a next turn from the first and second reception codewords on the basis of the shared bit value and a bit value of the next turn.

5. The wireless communication terminal of claim 3, wherein, when bit values of all the turns of the first and second reception codewords are estimated, the combination block outputs a set of the estimated bit values in parallel.

6. The wireless communication terminal of claim 5, further comprising a transformation block configured to obtain fixed bits and information bits by performing matrix multiplication on the set of the estimated bit values and F^{⊗n}(n=log₂N).

7. The wireless communication terminal of claim 3, wherein the designated turns are determined in accordance with a tree structure of the SCD.

8. The wireless communication terminal of claim 6, wherein each of the first and second estimation blocks includes an LLR estimator, and
the combination block and the transformation block are included in an LLR combining polar decoder.

9. A method of decoding a polar code by at least one processor, the method comprising:
respectively receiving, by first and second antennas, signals including same information transmitted from a transmitting-side device via different channels;
performing digital conversion on the signals respectively received through the first and second antennas and demodulating the signals to acquire first and second reception codewords; and
combining log likelihood ratio (LLR) values of the first and second reception codewords with each other and then sequentially performing successive cancellation (SC) decoding (SCD) bit by bit using a combined LLR value for estimating a next LLR value.

10. The method of claim 9, wherein the signals are encoded using systematic polar code by the transmitting-side device.

11. The method of claim 9, wherein the sequential performing of the SCD comprises:
sequentially estimating LLR values of the first reception codeword in order of designated turns;
sequentially estimating LLR values of the second reception codeword in order of designated turns; and
combining respectively estimated LLR values of each turn and sequentially estimating a bit value of each turn on the basis of a combined bit value.

12. The method of claim 11, further comprising sharing the estimated bit value with the first and second estimation blocks,
wherein the sequential estimating of the LLR values of the first reception codeword comprises estimating an LLR value of a next turn from the first reception codeword on the basis of the shared bit value and a bit value of the next turn, and
the sequential estimating of the LLR values of the second reception codeword comprises estimating an LLR value of a next turn from the second reception codeword on the basis of the shared bit value and the bit value of the next turn.

13. The method of claim 11, further comprising, when bit values of all the turns of the first and second reception codewords are estimated, outputting a set of the estimated bit values in parallel.

14. The method of claim 13, further comprising performing matrix multiplication on the set of the estimated bit values and FOR (n=log 2N) to obtain fixed bits and information bits.

15. The method of claim 11, wherein the designated turns are determined in accordance with a tree structure of the SCD.

16. A decoding module, comprising:
a first estimation block and a second estimation block configured to sequentially estimate a first log likelihood ratio (LLR) value and a second LLR value in order of designated turns for first and second reception codewords acquired via different channels; and
a combination block configured to combine the first and second LLR values with each other and estimate a bit value of each turn on the basis of the combined value,
wherein the first and second estimation blocks estimate a next LLR value using a bit value estimated by the combination block.

17. The decoding module of claim 16, wherein the first and second reception codewords are encoded using systematic polar code at a transmitting-side device.

18. The decoding module of claim 16, wherein the combination block shares the estimated bit value with the first and second estimation blocks, and
the first and second estimation blocks estimate LLR values of a next turn from the first and second reception codewords on the basis of the shared bit value and a bit value of the next turn.

19. The decoding module of claim 16, wherein, when bit values of all the turns of the first and second reception codewords are estimated, the combination block outputs a set of the estimated bit values in parallel.

20. The decoding module of claim 19, further comprising a transformation block configured to obtain fixed bits and information bits by performing matrix multiplication on the set of the estimated bit values and F^{⊗n} (n=log 2N).
